(19) United States
(12) Patent Application Publication
(10) Pub. No.: US 2025/0346053 A1
(43) Pub. Date: Nov. 13, 2025

(54) IMAGE FORMING APPARATUS AND ADJUSTMENT METHOD FOR THE IMAGE FORMING APPARATUS

(71) Applicant: CANON KABUSHIKI KAISHA, Tokyo (JP)

(72) Inventors: MIKIHIKO WATANABE, Ibaraki (JP); JUNICHI MOTEKI, Chiba (JP)

(21) Appl. No.: 19/194,865

(22) Filed: Apr. 30, 2025

(30) Foreign Application Priority Data
May 10, 2024 (JP) 2024-077476

(51) Int. Cl. B41J 29/02; B41J 11/00; B41J 29/13; H05K 5/02; H05K 5/13; H05K 5/30

(52) U.S. Cl. CPC B41J 29/02; B41J 11/007; B41J 29/13; H05K 5/0234; H05K 5/13; H05K 5/30

(57) ABSTRACT

An image forming apparatus includes a first casing, a second casing, a fixing member and an adjusting member. The second casing is connected to the first casing such that the first casing and the second casing are arranged along a first direction orthogonal to a vertical direction. The fixing member connects the first casing and the second casing at a first height position in the vertical direction. The adjusting member connects the first casing and the second casing at a second height position in the vertical direction different from the first height position such that a distance between the first casing and the second casing is adjustable. The first casing and the second casing are fixed to each other with the distance adjusted to a predetermined distance by at least the fixing member and the adjusting member.

### BACKGROUND OF THE INVENTION

### Field of the Invention

The present invention relates to an image forming apparatus that is, for example, a copying machine, a printer, a facsimile, or a multi-function printer having a plurality of functions of these apparatuses, and that is constituted by connecting a plurality of casings to each other, and to an adjustment method for the image forming apparatus.

### Description of the Related Art

An image forming apparatus has a known configuration in which a plurality of casings can be connected to and separated from each other. In such a configuration, each casing has a conveyance path for recording materials, and if a conveyance path of one of two casings separated from each other is separated from or slants with respect to a conveyance path of the other of the two casings, the failure in conveyance of a recording material, such as a jam or skew, may occur when the recording material is conveyed from the one to the other of the two casings. As countermeasures, Japanese Patent Application Publication No. 2018-159739 proposes a configuration in which the angle formed by the conveyance paths of two casings is made appropriate by using a rotary shaft mechanism disposed on the back side of the two casings and an inter-casing distance adjustment member disposed on the front side.

However, in the configuration described in Japanese Patent Application Publication No. 2018-159739, although the distance between the two casings is adjusted on the front side and the back side of the casings, there is a case where the distance between the two casings is required to be adjusted in a vertical direction. For example, an installation surface on which the apparatus is installed is not necessarily flat. In a case where a plurality of casings separated from each other is connected to each other in the installation of an apparatus, the apparatus is often large in size. Thus, the area of the installation surface is also large, so that the apparatus will be more easily affected by the slope of the installation surface. In such a case, it is especially required that the distance between two casings be adjusted in the vertical direction.

For example, the distance between two casings can be adjusted in the vertical direction by connecting the two casings to each other while measuring the distance between the two casings on each of an upper side and a lower side of the casings. However, in the case where the two casings are connected to each other while the distance between the casings is measured on each of the upper side and the lower side of the casings, the operation takes time and is troublesome.

### SUMMARY OF THE INVENTION

The present invention provides a configuration and a method that allow the distance between two casings to be adjusted easily in the vertical direction.

According to a first aspect of the present invention, an image forming apparatus configured to form an image on a recording material, the image forming apparatus includes a first casing including a first conveyance path through which a recording material is conveyed, a second casing connected to the first casing such that the first casing and the second casing are arranged along a first direction orthogonal to a vertical direction, and including a second conveyance path which is connected to the first conveyance path, and through which the recording material from the first conveyance path is conveyed, a fixing member configured to connect the first casing and the second casing at a first height position in the vertical direction such that a first distance between the first casing and the second casing in the first direction at the first height position is fixed, and, an adjusting member configured to connect the first casing and the second casing at a second height position in the vertical direction different from the first height position such that a second distance between the first casing and the second casing in the first direction at the second height position is adjustable. The first casing and the second casing are fixed to each other with the second distance adjusted to a predetermined distance by at least the fixing member and the adjusting member.

According to a second aspect of the present invention, an adjustment method for an image forming apparatus. The image forming apparatus is configured to form an image on a recording material. The image forming apparatus includes a first casing including a first conveyance path through which a recording material is conveyed, and, a second casing connected to the first casing such that the first casing and the second casing are arranged along a first direction orthogonal to a vertical direction, and including a second conveyance path which is connected to the first conveyance path, and through which the recording material from the first conveyance path is conveyed. The adjustment method includes fixing a first distance between the first casing and the second casing in the first direction at a first height position in a vertical direction, adjusting a second distance between the first casing and the second casing in the first direction at a second height position in the vertical direction different from the first height position after the first distance is fixed at the first height position, and, fixing the first casing and the second casing each other at the second height position after the second distance is adjusted.

Further features of the present invention will become apparent from the following description of exemplary embodiments with reference to the attached drawings.

### BRIEF DESCRIPTION OF THE DRAWINGS

FIG. 1 is a cross-sectional view illustrating a schematic configuration of an ink-jet recording apparatus of an embodiment.

FIG. 2 is a perspective view of a first casing of the embodiment.

FIG. 3 is a left side view of the first casing of the embodiment.

FIG. 4 is a perspective view of a second casing of the embodiment.

FIG. 5 is a right side view of the second casing of the embodiment.

FIG. 6 is a front view illustrating a state where the first casing and the second casing of the embodiment are connected to each other.

FIG. 7 is a back view illustrating a state where the first casing and the second casing of the embodiment are connected to each other.

FIG. 8A is a perspective view of a caster of the embodiment.

FIG. 8B is a cross-sectional view of the caster of the embodiment.

FIG. 9A is a schematic diagram in which a state where the first casing and the second casing of the embodiment are connected to each other is viewed from above.

FIG. 9B is a diagram illustrating the adjustment of distance between the first casing and the second casing of the embodiment.

FIG. 10A is a front view of an adjusting member of the embodiment.

FIG. 10B is a perspective view in which the adjusting member of the embodiment is viewed from the front side.

FIG. 10C is a perspective view in which the adjusting member of the embodiment is viewed from the back side.

FIG. 11A is an enlarged view of a scale and an indicating portion of the adjusting member of the embodiment, the scale being formed in an X direction.

FIG. 11B is an enlarged view of a scale and an indicating portion of the adjusting member of the embodiment, the scale being formed in a Z direction.

FIG. 12 is a perspective view illustrating a state where the first casing and the second casing of the embodiment are connected to each other via the adjusting member on the front side.

FIG. 13 is a perspective view illustrating a state where the first casing and the second casing of the embodiment are connected to each other via the adjusting member on the back side.

FIG. 14 is a perspective view illustrating a state where the first casing and the second casing of the embodiment are connected to each other via a fixing member on the front side.

FIG. 15A is a diagram illustrating the adjustment performed in the Z direction in the connecting operation for the first casing and the second casing of the embodiment.

FIG. 15B is a diagram illustrating a state where a second connecting member is positioned to the second casing in the connecting operation for the first casing and the second casing of the embodiment.

FIG. 15C is a diagram illustrating a state where a lower portion of the first casing and a lower portion of the second casing are connected to each other via the fixing member in the connecting operation for the first casing and the second casing of the embodiment.

FIG. 16 is a diagram illustrating a state where the distance between the first casing and the second casing is adjusted in a state where the lower portion of the first casing and the lower portion of the second casing are not connected to each other via the fixing member.

### DESCRIPTION OF THE EMBODIMENTS

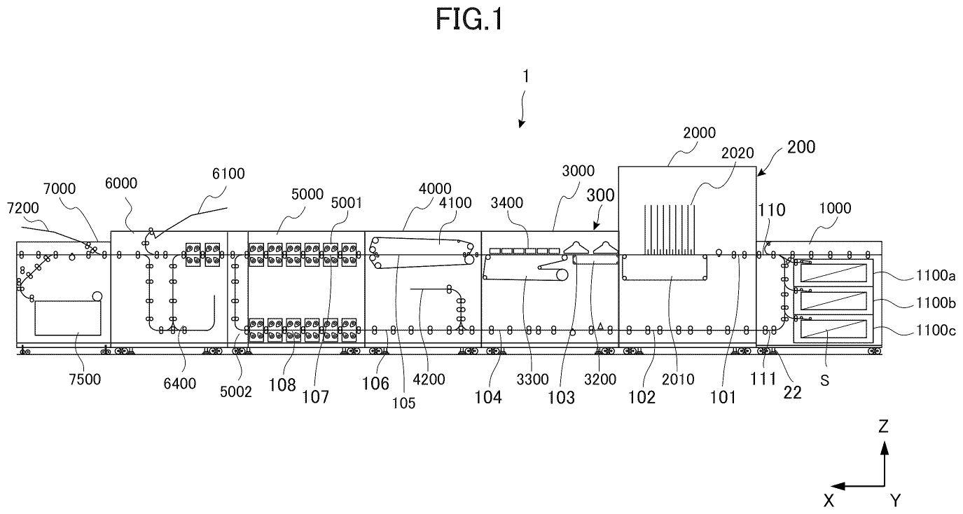

An embodiment will be described with reference to FIGS. 1 to 16. First, a schematic configuration of an inkjet recording apparatus of the present embodiment will be described with reference to FIG. 1.

### An Inkjet Recording Apparatus

The inkjet recording apparatus 1 serving as an image forming apparatus of the present embodiment uses an inkjet recording system that ejects ink to form an image on a sheet, and is a so-called sheet-type inkjet recording apparatus that forms an ink image on a sheet using two liquids of a reaction liquid and ink. The sheet may be, for example, a recording material capable of receiving ink, such as paper such as plain paper or thick paper, a plastic film such as a sheet for an overhead projector, a sheet having a special shape such as an envelope or index paper, and cloth.

As illustrated in FIG. 1, the inkjet recording apparatus 1 of the present embodiment includes a feeding module 1000, a print module 2000, a drying module 3000, a fixing module 4000, a cooling module 5000, a reverse module 6000, and a stacking module 7000. When the sheet S supplied from the feeding module 1000 is conveyed along a conveyance path in each module, various processing is performed, and the sheet S is finally discharged to the stacking module 7000.

The feeding module 1000, the print module 2000, the drying module 3000, the fixing module 4000, the cooling module 5000, the reverse module 6000, and the stacking module 7000 have separate casings, and these casings are connected to configure the inkjet recording apparatus 1.

The feeding module 1000 includes cassettes 1100a, 1100b, and 1100c in which the sheet S, which serves as a recording material, is stored, and conveyance paths 110 and 111 through which the sheet S is conveyed. The cassettes 1100a to 1100c are disposed so as to be able to be drawn toward the front side of the apparatus for storing the sheet S. The sheet S is fed, one by one, by a separation belt and a conveyance roller in each of the cassettes 1100a to 1100c, and is conveyed to the print module 2000 through the conveyance path 110. Note that the number of the cassettes 1100a to 1100c is not limited to three. For example, the feeding module 1000 may include one, two, or four or more cassettes. The conveyance path 111 is disposed below the conveyance path 110 in the vertical direction. As described below, the conveyance path 111 is a conveyance path through which the sheet S is conveyed in the double-side printing. The conveyance path 111 is connected to the conveyance path 110.

The print module 2000 that serves as an image forming portion includes conveyance paths 101 and 102 through which the sheet S is conveyed, a pre-formation registration correction portion (not illustrated), a print belt unit 2010, and a recording portion 2020. The sheet S fed from the feeding module 1000 is conveyed from the conveyance path 110 of the feeding module 1000 to the conveyance path 101 of the print module 2000. Then the skew and the position of the sheet S are corrected by the pre-formation registration correction portion disposed on the conveyance path 101, and the sheet S is conveyed to the print belt unit 2010 that constitutes the conveyance path 101. The conveyance path 102 is disposed below the conveyance path 101 in the vertical direction. As described below, the conveyance path 102 is a conveyance path through which the sheet S is conveyed in the double-side printing. The recording portion 2020 is disposed at a position that faces the print belt unit 2010. The recording portion 2020 is an ink-jet recording portion that forms an image by causing a recording head to eject ink onto the sheet S. The recording head ejects the ink from a position above the sheet S that is being conveyed. Specifically, a plurality of recording heads, which ejects the ink, is disposed along the conveyance direction. In the present embodiment, the recording portion 2020 includes line-type recording heads whose number is five in total. The line-type recording heads correspond to a reaction liquid in addition to four colors of ink of Y (yellow), M (magenta), C (cyan), and Bk (black). The clearance between the recording head and the sheet S is ensured by the sheet S being attracted and conveyed by the print belt unit 2010.

Note that the number of colors of ink and the number of recording heads are not limited to the above-described five. As the inkjet method, a method using a heat generating element, a method using a piezoelectric element, a method using an electrostatic element, a method using a micro electro mechanical systems (MEMS) element, and the like can be adopted. The ink of each color is supplied from each ink tank (not illustrated) to each recording head via each ink tube. The ink contains “0.1 mass % to 20.0 mass %” of a resin component, water, a water-soluble organic solvent, a coloring material, wax, an additive, and the like on the basis of the total mass of the ink.

When the sheet S on which an image is formed by the recording portion 2020 is conveyed by the print belt unit 2010, deviation and color density of the image formed on the sheet S are detected by an in-line scanner (not illustrated) arranged downstream of the recording portion 2020 in the conveyance direction of the sheet S. Based on the deviation and the color density of the image detected by the in-line scanner, deviation of an image, density of an image, and the like to be formed on the sheet S are corrected.

The drying module 3000 that serves as a drying apparatus includes conveyance paths 103 and 104 through which the sheet S is conveyed, a decoupling portion 3200, a drying belt unit 3300, and a warm-air blowing portion 3400. For increasing the fixability of ink to the sheet S in the following fixing module 4000, the drying module 3000 reduces liquid components of the ink and the reaction liquid applied to the sheet S. The sheet S on which an image has been formed in the print module 2000 is conveyed from the conveyance path 101 of the print module 2000 to the conveyance path 103 of the drying module 3000. Then the sheet S is conveyed to the decoupling portion 3200 that is disposed in the drying module 3000, and that constitutes the conveyance path 103. In the decoupling portion 3200, the frictional force is produced between the sheet S and a belt by the wind pressure of wind that is blown on the sheet S from above, and the sheet S is conveyed by the belt. Since the sheet S placed on the belt is conveyed by the frictional force in this manner, the deviation of the sheet S is prevented when the sheet S is conveyed from the print belt unit 2010 to the decoupling portion 3200. The sheet S conveyed from the decoupling portion 3200 is attracted and conveyed by the drying belt unit 3300 that constitutes the conveyance path 103, and the ink and the reaction liquid applied to the sheet S is dried by the warm-air blowing portion 3400, disposed above the belt, blowing warm air on the sheet S.

Since the ink and the reaction liquid applied to the sheet S are heated and the evaporation of moisture is facilitated by the drying module 3000, so-called cockling can be prevented from occurring. The cockling is border-like lines formed around the ink applied to the sheet S and produced by the ink spattering onto the sheet S. The drying module 3000 may be any apparatus as long the apparatus can heat and dry the ink and the reaction liquid. Preferably, the drying module 3000 is a warmed-air dryer or a heater. It is preferable in safety and energy efficiency that the heater be a heating-wire heater or an infrared heater. In the drying system, a system that emits electromagnetic wave (such as ultraviolet rays or infrared rays) to the surface of the sheet S, or a heat transfer system that causes a heating element to contact the sheet S may be used, combined with the system that gives the warm air to the sheet S. The conveyance path 104 is disposed below the conveyance path 103 in the vertical direction. As described below, the conveyance path 104 is a conveyance path through which the sheet S is conveyed in the double-side printing.

The fixing module 4000 that serves as a fixing system includes conveyance paths 105 and 106 through which the sheet S is conveyed, and a fixing belt unit 4100 which serves as a fixing apparatus. The sheet S whose ink and the like have been dried in the drying module 3000 is conveyed from the conveyance path 103 of the drying module 3000 to the conveyance path 105 of the fixing module 4000. Then the sheet S is conveyed to the fixing belt unit 4100 that constitutes the conveyance path 105. The fixing belt unit 4100 fixes the ink to the sheet S by causing the sheet S to pass through a space between an upper belt unit and a lower belt unit that are heated. The conveyance path 106 is disposed below the conveyance path 105 in the vertical direction. As described below, the conveyance path 106 is a conveyance path through which the sheet S is conveyed in the double-side printing.

The cooling module 5000 includes conveyance paths 107 and 108 through which the sheet S is conveyed, and a plurality of cooling portions 5001. The sheet S whose ink has been fixed in the fixing module 4000 is conveyed from the conveyance path 105 of the fixing module 4000 to the conveyance path 107 of the cooling module 5000. On the conveyance path 107, the plurality of cooling portions 5001 are disposed for cooling the sheet S that is being conveyed. The high-temperature sheet S conveyed from the fixing module 4000 is cooled by the cooling portions 5001. For example, each of the cooling portions 5001 cools the sheet S by increasing the pressure of a corresponding cooling box by taking the external air in the cooling box by using a fan, and by causing the pressure of the cooling box to blow the wind from the cooling box onto the sheet S through a nozzle. The cooling portions 5001 are disposed on both sides of the conveyance paths 107 and 108 of the sheet S, and cool both sides of the sheet S. The conveyance path 108 is disposed below the conveyance path 107 in the vertical direction. As described below, the conveyance path 108 is a conveyance path through which the sheet S is conveyed in the double-side printing.

The cooling module 5000 includes a conveyance-path switch portion 5002. The conveyance-path switch portion 5002 switches the conveyance path of the sheet S, depending on a case where the sheet S is conveyed to the reversing module 6000, and on a case where the sheet S is conveyed to the conveyance path 108, which is a duplex conveyance path, in the double-side printing in which images are formed on both sides of the sheet S.

The reverse module 6000 includes a reverse portion 6400. The reverse portion 6400 reverses the front and back sides of the conveyed sheet S and changes the front and back sides of the sheet S when the sheet S is discharged to the stacking module 7000. The stacking module 7000 includes a top tray 7200 and a stacking portion 7500, and stacks the sheet S conveyed from the reverse module 6000.

In the double-side printing, the sheet S is conveyed to the conveyance path 108 disposed in a lower portion of the cooling module 5000, by the conveyance-path switch portion 5002. Then the sheet S is returned to the conveyance path 101 of the print module 2000 through the conveyance path 106 disposed in a lower portion of the fixing module 4000, the conveyance path 104 disposed in a lower portion of the drying module 3000, the conveyance path 102 disposed in a lower portion of the print module 2000, the conveyance path 111 disposed in a lower portion of the feeding module 1000, and the conveyance path 110. On the conveyance path 106 that is a duplex conveyance path of the fixing module 4000, a reversing portion 4200 that reverses the front side and back side of the sheet S is disposed. In the double-side printing, the front side and the back side of the sheet S is reversed by the reversing portion 4200. The sheet S whose front side and the back side have been reversed is returned to the print module 2000, as described above, through the conveyance paths 106, 104, 102, 111, and 110. Then, an image is formed also on the other side (on which no image is formed) of the sheet S that has been returned to the print module 2000, and the sheet S is discharged to the stacking module 7000 through the drying module 3000, the fixing module 4000, the cooling module 5000, and the reversing module 6000.

### Order and Configuration for Positioning Casings

Next, order and a configuration for positioning casings of the above-described modules will be described. By the way, there is a case where the image forming apparatus is upsized for increasing the productivity. However, if the apparatus is upsized, the weight of the apparatus increases, and it becomes difficult to carry the apparatus. For example, it becomes difficult to carry the apparatus to a place to which the apparatus is to be delivered, because the elevator has a limited size. In addition, it becomes difficult to access a component disposed in the apparatus, in the maintenance or an abnormal state of the apparatus. For these reasons, there is a case where the apparatus is separated into a plurality of casings in a direction parallel to the installation surface, and the casings are connected to each other when installed. Also in the ink-jet recording apparatus 1 of the present embodiment, a plurality of modules is connected to each other. As described above, in each of the modules, a corresponding conveyance path is formed for conveying the recording material. Thus, the recording material is delivered from one module to another adjacent to the one module. Thus, it is necessary to connect adjacent modules to each other in a position appropriate for each other so that a conveyance path in one module and a conveyance path in another module are not shifted from each other.

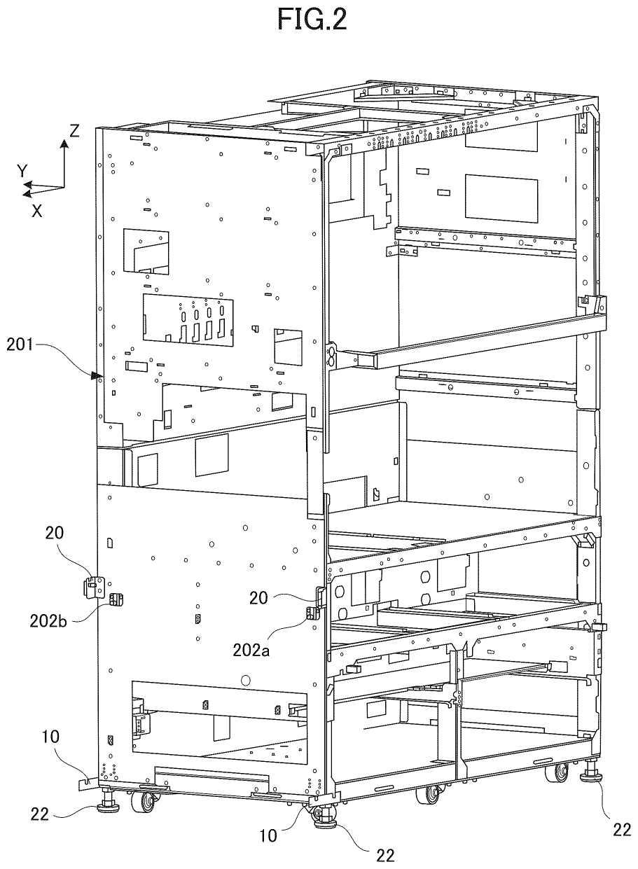

In a case where the ink-jet recording apparatus 1 of the present embodiment is installed on an installation surface, the print module 2000 is placed first, and then the print module 2000 is fixed by bringing adjusters 22 into contact with the installation surface. Then the feeding module 1000 and the drying module 3000 are positioned with respect to the print module 2000, and then the fixing module 4000 is positioned with respect to the drying module 3000. In this manner, based on the print module 2000, an adjacent module is positioned in a sequential manner. Since each module is positioned in the same manner, the description will be made, in the present embodiment, for the positioning between a casing of the print module 2000 and a casing of the drying module 3000. The casing of the print module 2000 is referred to as a first casing 200, and the casing the drying module 3000 is referred to as a second casing 300. First, the position and general use of each component will be described with reference to FIGS. 2 to 5. For convenience of description, FIGS. 2 to 5 illustrate only frames and some covers of the first casing 200 and the second casing 300. The frame of the first casing 200 is referred to as a first frame 201, and the frame of the second casing 300 is referred to as a second frame 301.

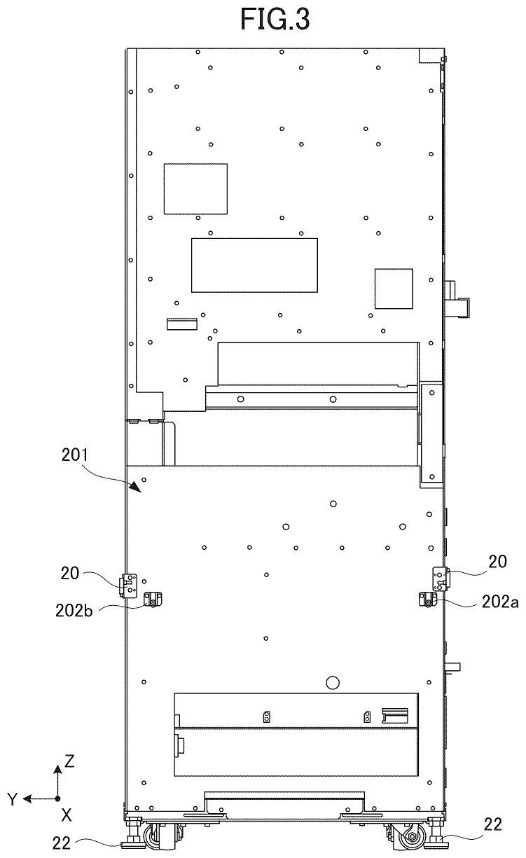

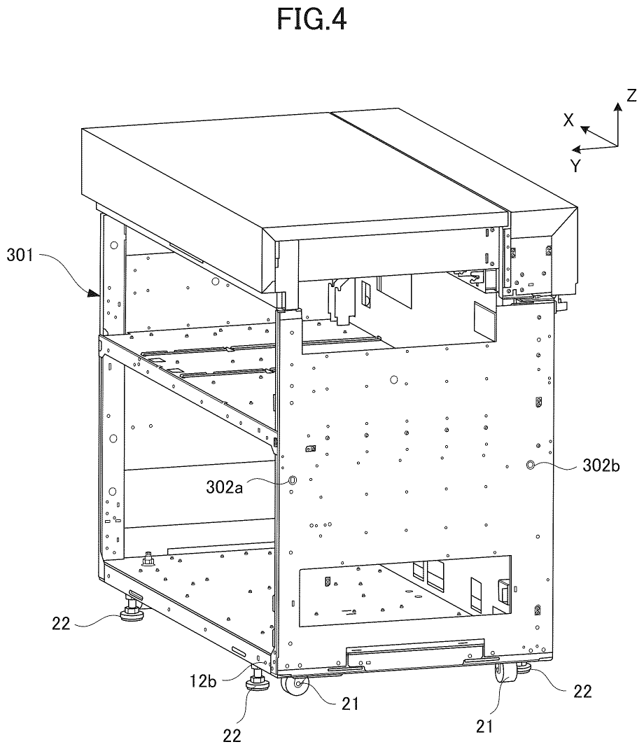

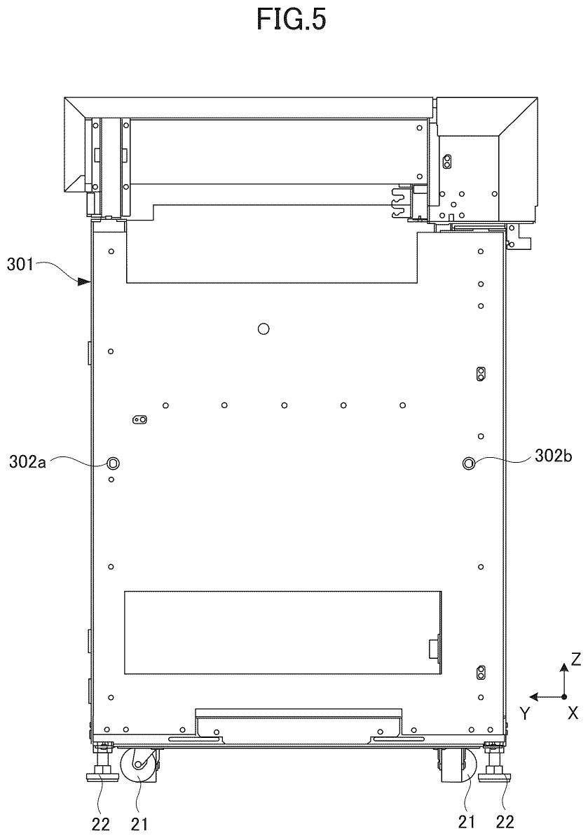

FIG. 2 is a perspective view of the first frame 201 that constitutes the first casing 200, and FIG. 3 is a left side view of the first frame 201 that constitutes the first casing 200. FIG. 4 is a perspective view of the second frame 301 that constitutes the second casing 300, and FIG. 5 is a right side view of the second frame 301 that constitutes the second casing 300. Note that the right described in the present embodiment is the right of the ink-jet recording apparatus 1 viewed from the front side of the ink-jet recording apparatus 1, or the right side in FIG. 1. In addition, the left described in the present embodiment is the left of the ink-jet recording apparatus 1 viewed from the front side of the ink-jet recording apparatus 1, or the left side in FIG. 1. On the front side of the ink-jet recording apparatus 1, an operation portion (not illustrated) operated by an operator is disposed.

In addition, an X direction (i.e., a first direction) in each drawing is a right and left direction. In the present embodiment, the X direction is a conveyance direction of the recording material, and a horizontal direction. A Y direction (i.e., a second direction) is a front and back direction of the apparatus. A Z direction is a vertical direction of the apparatus. In the present embodiment, the Z direction is a substantially vertical direction. The X direction, the Y direction, and the Z direction are orthogonal to each other. The first casing 200 and the second casing 300 is connected to each other such that the first casing 200 and the second casing 300 are arranged along the X direction. In the present embodiment, the first casing 200 and the second casing 300 can be connected to and separated from each other in the X direction. That is, the drying module 3000 is connected to the left side of the print module 2000. Note that in the present embodiment, casings of modules adjacent to each other can be connected to and separated from each other in the X direction.

In FIGS. 2 and 3, in the left side-surface of the first frame 201 that constitutes the first casing 200, positioning shafts 202a and 202b are formed as a first fitting portion. The positioning shaft 202a is formed in the left side-surface of the first frame 201 on the front side, and the positioning shaft 202b is formed in the left side-surface of the first frame 201 on the back side. The positioning shafts 202a and 202b are formed, spaced from each other in the front and back direction. The positioning shafts 202a and 202b project toward the second frame 301 side (the second frame 301 constitutes the second casing 300), that is, toward the left side.

In FIGS. 4 and 5, in the right side-surface of the second frame 301 that constitutes the second casing 300, fitting holes 302a and 302b are formed as a second fitting portion. The fitting hole 302a is formed in the right side-surface of the second frame 301 on the front side, and the fitting hole 302b is formed in the right side-surface of the second frame 301 on the back side. The fitting holes 302a and 302b are formed, spaced from each other in the front and back direction. Each of the fitting holes 302a and 302b is a long hole elongated along the vertical direction (i.e., the Z direction or a height direction). That is, a width of each of the fitting holes 302a and 302b in the front and back direction (i.e., the Y direction) is substantially equal to or slightly larger than the outer diameter of each of the positioning shafts 202a and 202b. In addition, a width of each of the fitting holes 302a and 302b in the vertical direction is sufficiently larger than the outer diameter of each of the positioning shafts 202a and 202b.

For connecting the first casing 200 and the second casing 300, the positioning shafts 202a and 202b of the first frame 201 are inserted into and engaged with the fitting holes 302a and 302b of the second frame 301. With this operation, a relative position of the second casing 300 with respect to the first casing 200 in the front and back direction (i.e., the Y direction) is fixed. Note that since the positioning of the second casing 300 in the front and back direction may be performed by using any one of the positioning shafts 202a and 202b, the width of one of the fitting holes 302a and 302b of the second frame 301 may be larger than the width of the other of the fitting holes 302a and 302b in the front and back direction. In addition, in a state where the positioning shafts 202a and 202b and the fitting holes 302a and 302b are fit to each other, the second casing 300 can be moved with respect to the first casing 200 in the vertical direction, by the clearance between the positioning shaft 202a and the fitting hole 302a in the vertical direction or the clearance between the positioning shaft 202b and the fitting hole 302b in the vertical direction.

Note that the relationship between the positioning shafts and the fitting holes may be reversed. In another case, a positioning shaft and a fitting hole may be formed in each of both casings. For example, the fitting holes may be formed in the left side-surface of the first casing 200, and the positioning shafts may be formed in the right side-surface of the second casing 300. In another case, a positioning shaft and a fitting hole may be formed in the left side-surface of the first casing 200, and a fitting hole into which the positioning shaft formed in the first casing 200 can be fit, and a positioning shaft which can be fit into the fitting hole formed in the first casing 200 may be formed in the right side-surface of the second casing 300.

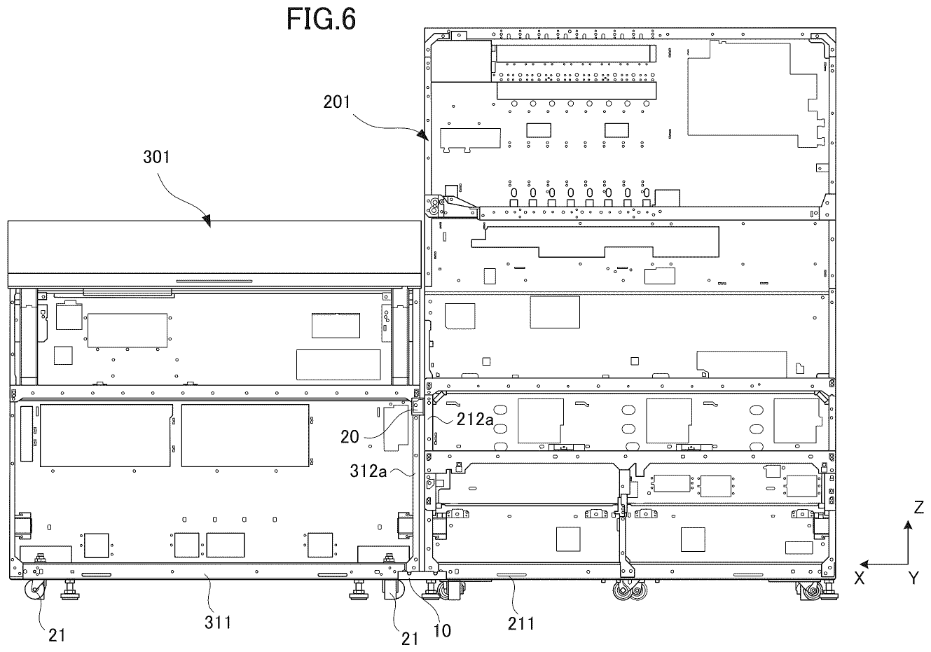

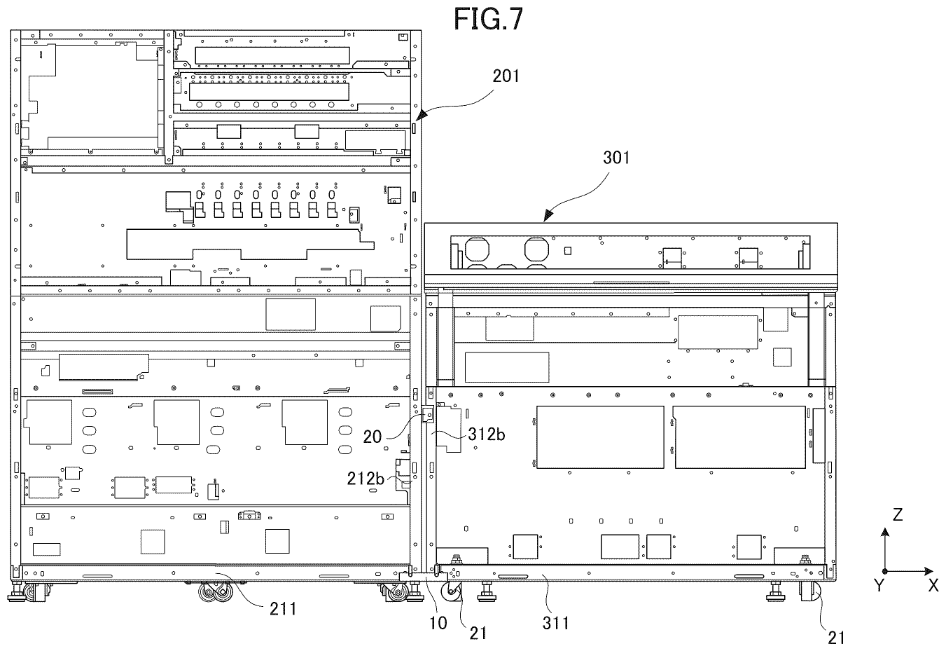

FIGS. 6 and 7 illustrate a state where the first frame 201 of the first casing 200 and the second frame 301 of the second casing 300 are connected to each other. FIG. 6 is a diagram in which a state where the first frame 201 and the second frame 301 are connected to each other is viewed from the front side. FIG. 7 is a diagram in which a state where the first frame 201 and the second frame 301 are connected to each other is viewed from the back side. As described above, the positioning shafts 202a and 202b and the fitting holes 302a and 302b are fit to each other, so that the first frame 201 and the second frame 301 are positioned in the front and back direction. After that, as described below, a bottom plate 211 of the first frame 201 and a bottom plate 311 of the second frame 301 are fixed by a fixing member 10. In addition, a left pillar 212a of the first frame 201 and a right pillar 312a of the second frame 301 are fixed by one adjusting member 20, and a left pillar 212b of the first frame 201 and a right pillar 312b of the second frame 301 are fixed by the other adjusting member 20. With this operation, the first casing 200 and the second casing 300 are connected to each other.

### Configuration and Height Adjustment of Caster

Each of the above-described first casing 200 and second casing 300 includes a plurality of casters 21 that serves as vertical direction adjustment portions. The plurality of casters 21 is disposed on each of the bottom surface of the bottom plate 211 of the first frame 201 and the bottom surface of the bottom plate 311 of the second frame 301. The casters 21 can adjust the position of the first casing 200 and the second casing 300 in the vertical direction, with respect to the installation surface on which the first casing 200 and the second casing 300 are installed. In the present embodiment, the position of the second casing 300 with respect to the first casing 200 is adjusted by the casters 21.

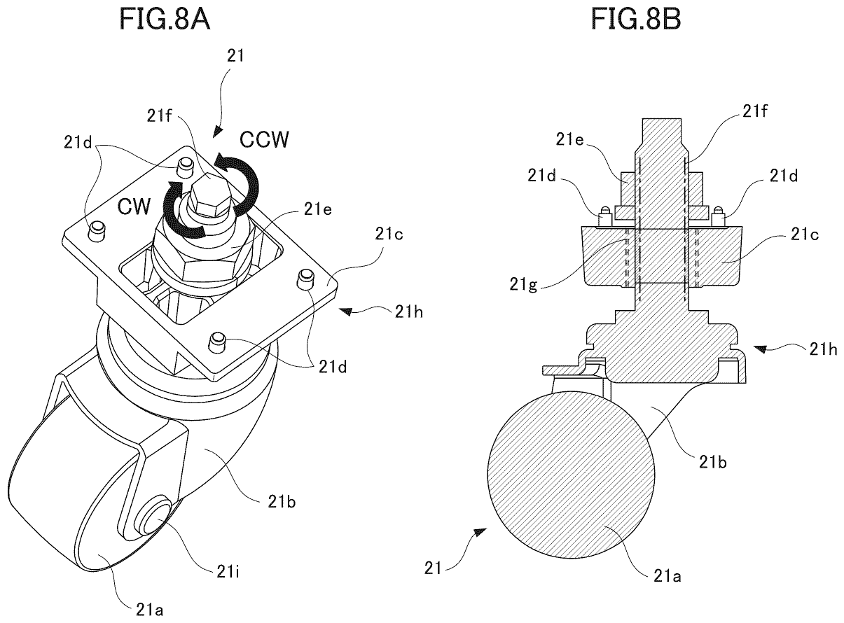

Next, a configuration of the caster 21 will be described with reference to FIGS. 8A and 8B. FIG. 8A is a perspective view of the caster 21 in which the caster 21 is viewed from above. FIG. 8B is a cross-sectional view of the caster 21. The caster 21 includes a wheel 21a that contacts the installation surface, and a vertical position changing portion 21h. The vertical position changing portion 21h is fixed to the first casing 200 or the second casing 300, and the position of the vertical position changing portion 21h is adjustable with respect to the wheel 21a in the vertical direction. The vertical position changing portion 21h includes a main body 21b, a base portion 21c, and a nut 21e.

The wheel 21a is rotatably attached to the main body 21b via a rotation shaft 21i. In the main body 21b, a male screw portion 21f is formed. On the other hand, in the base portion 21c, a female screw portion 21g that can be screw-fit to the male screw portion 21f is formed. The base portion 21c is joined with the bottom surface of the bottom plate 211 of the first frame 201 or the bottom surface of the bottom plate 311 of the second frame 301 via screws 21d. In addition, in a state where the female screw portion 21g of the base portion 21c is screw-fit to the male screw portion 21f of the main body 21b, the nut 21e is screw-fit to the male screw portion 21f so that the base portion 21c and the main body 21b do not separate from each other.

In a case where the position (height) of the first casing 200 and the second casing 300 in the vertical direction is to be adjusted by using the caster 21, the nut 21e is loosened, and the male screw portion 21f is rotated. Hereinafter, the description will be made for the height adjustment of the second casing 300. However, the height adjustment of the first casing 200 can be performed in the same manner. For example, if the male screw portion 21f is rotated in a clockwise direction (i.e., a CW direction) in FIG. 8A, with respect to the base portion 21c, the wheel 21a of the caster 21 moves in a direction in which the wheel 21a is separated from the bottom plate 311. That is, the wheel 21a of the caster 21 moves downward relative to the bottom plate 311. In this manner, the second casing 300 can be lifted.

On the other hand, if the male screw portion 21f is rotated in a counterclockwise direction (i.e., a CCW direction) in FIG. 8A, with respect to the base portion 21c, the wheel 21a of the caster 21 moves in a direction in which the wheel 21a approaches the bottom plate 311. That is, the wheel 21a of the caster 21 moves upward relative to the bottom plate 311. In this manner, the second casing 300 can be lowered. Note that the male screw portion 21f can be rotated by rotating the wheel 21a and the main body 21b together with respect to the base portion 21c in a state where the base portion 21c is fixed to the bottom plate 311.

In this manner, by rotating the male screw portion 21f with respect to the base portion 21c, the position of the second casing 300 relative to the first casing 200 in the height direction can be adjusted. For example, in a case where the second casing 300 is located lower than the first casing 200 (in the-Z direction), the second casing 300 is lifted by rotating the male screw portion 21f in the CW direction.

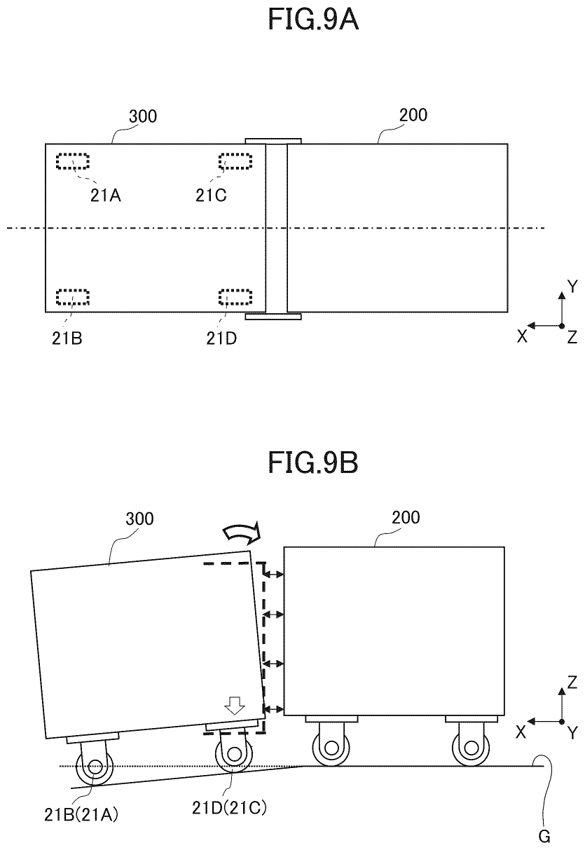

The caster 21 can perform not only the adjustment of the first casing 200 and the second casing 300 in the Z direction (i.e., the vertical direction), but also the fine adjustment in the X direction (i.e., the right and left direction). Hereinafter, the fine adjustment will be described with reference to FIGS. 9A and 9B. FIG. 9A is a schematic diagram in which the first casing 200 and the second casing 300 are viewed from above. FIG. 9B is a schematic diagram in which the first casing 200 and the second casing 300 are viewed from the front side.

As illustrated in FIG. 9A, the casters 21 are disposed at four corners of each casing (the casters 21 of the first casing 200 are not illustrated in FIG. 9A). The casters 21 disposed on the second casing 300 are referred to as casters 21A to 21D. The casters 21A and 21B are separated more from the first casing 200 than the casters 21C and 21D are. For example, there is a case where the second casing 300 slants, as illustrated in FIG. 9B, due to the slope of an installation surface G, and where the distance between an upper portion of the first casing 200 and an upper portion of the second casing 300 is larger. In this case, the adjustment is performed for reducing the distance between the upper portion of the first casing 200 and the upper portion of the second casing 300 by lowering the right side of the second casing 300 by rotating the male screw portion 21f of the caster 21C and the male screw portion 21f of the caster 21D by the same amount in the CCW direction. With this operation, the distance between the first casing 200 and the second casing 300 can be kept constant in the vertical direction.

### Adjusting Member

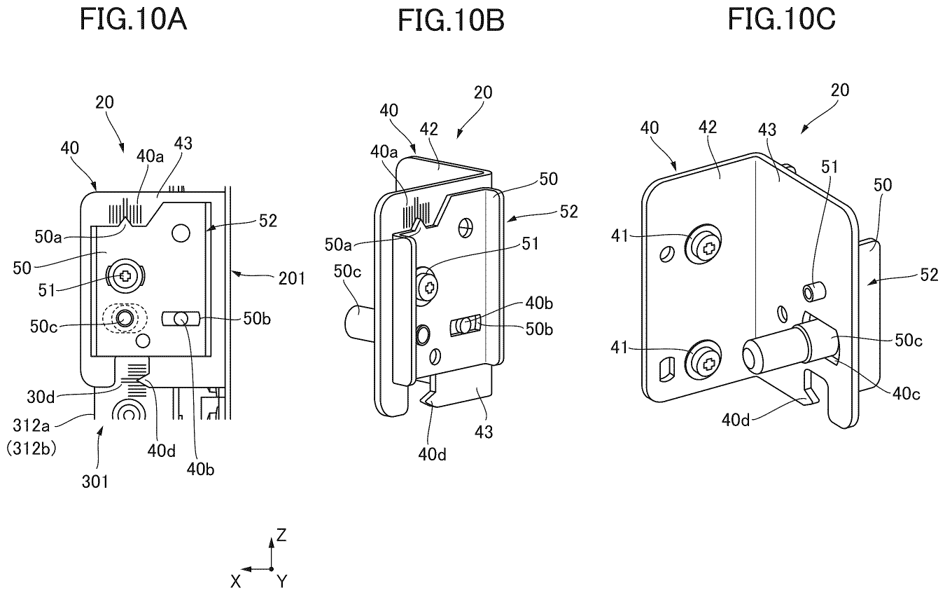

Next, an adjusting member 20 will be described with reference to FIGS. 10A to 13. Hereinafter, the description will be made for a case where the first casing 200 is the casing of the print module 2000 and the second casing 300 is the casing of the drying module 3000. However, the relationship between the casing and the module may be opposite to this. That is, the first casing 200 may be the casing of the drying module 3000, and the second casing 300 may be the casing of the print module 2000. In addition, the below-described relationship between the first casing 200 and the second casing 300 may be applied to the relationship between casings of other adjacent modules.

The adjusting member 20 connects the first casing 200 and the second casing 300 each other in a state where a distance (a second distance) between the first casing 200 and the second casing 300 in the X direction (i.e., the first direction) is adjusted. In other words, the adjusting member 20 that fixes the first casing 200 and the second casing 300 each other has a configuration that can adjust the distance between the first casing 200 and the second casing 300 in the X direction (i.e., the first direction). In the present embodiment, the adjusting member 20 is disposed on each of both sides in the front and back direction. Thus, the adjusting member 20 can fix the first casing 200 and the second casing 300 each other in a state where the distance between the first casing 200 and the second casing 300 in the X direction (i.e., the first direction) on the front side is adjusted, and where the distance between the first casing 200 and the second casing 300 in the X direction (i.e., the first direction) on the back side is adjusted. In addition, the adjusting member 20 can connect the first casing 200 and the second casing 300 each other at a second height position different, in the vertical direction, from a first height position in which the first casing 200 and the second casing 300 are connect each other by a below-described fixing member 10. In the present embodiment, the second height position is positioned above the first height position in the vertical direction. The first casing 200 and the second casing 300 are fixed to each other with the second distance adjusted to a predetermined distance by at least the fixing member 10 and the adjusting member 20.

As illustrated in FIGS. 10A to 10C, the adjusting member 20 includes a first connecting member 40 that serves as a connecting member, and a fastening portion 52. FIG. 10A is a front view in which a state where the adjusting member 20 is attached to the first frame 201 of the first casing 200 and the second frame 301 of the second casing 300 is viewed from the front side (or the back side). FIG. 10B is a perspective view in which the adjusting member 20 is viewed from the front side. FIG. 10C is a perspective view in which the adjusting member 20 is viewed from the back side.

The first connecting member 40 connects the first casing 200 and the second casing 300. The fastening portion 52 fastens the first connecting member 40 to the second casing 300. The fastening portion 52 includes a second connecting member 50, and a screw 51 that serves as a fastening member. The second connecting member 50 is positioned by a shaft 50c with respect to the second casing 300 in the X direction and the Z direction, and is fastened to the first connecting member 40 via the screw 51.

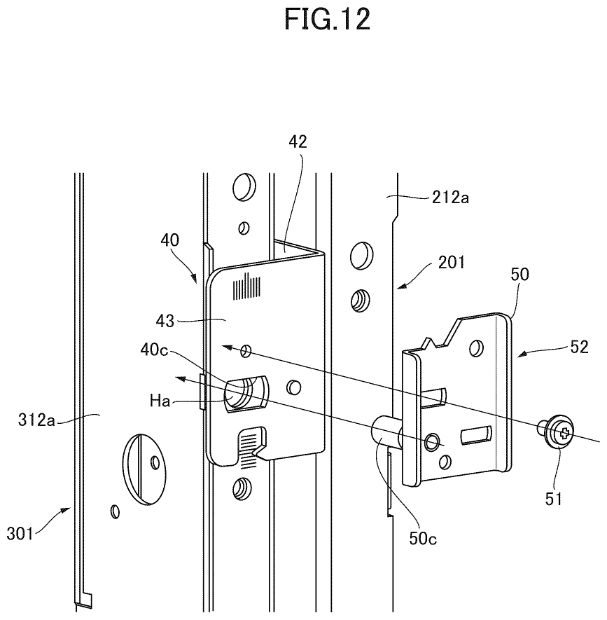

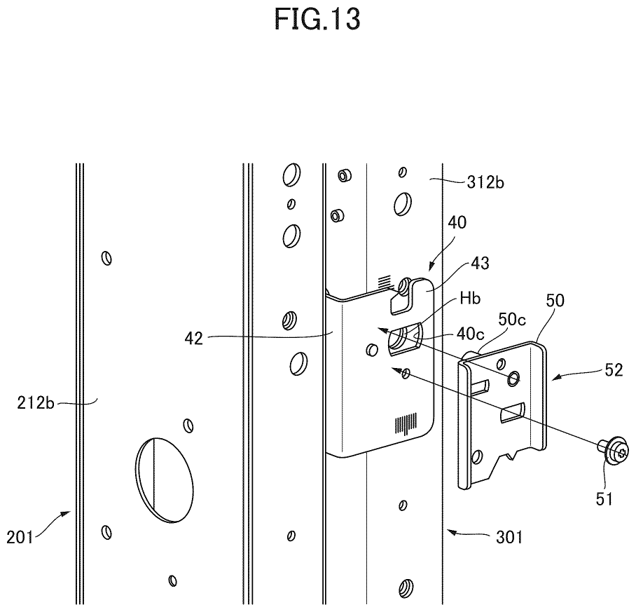

The first connecting member 40 includes a first plate portion 42 that serves as a fixing portion, and a second plate portion 43 that serves as a changing portion. The first plate portion 42 is fixed to the first casing 200. Specifically, as illustrated in FIGS. 12 and 13, the first plate portion 42 that constitutes one first connecting member 40 on the front side is fixed to a left pillar 212a that constitutes the first frame 201 of the first casing 200, via a screw 41 that serves as a fastening member, and the first plate portion 42 that constitutes the other first connecting member 40 on the back side is fixed to a left pillar 212b that constitutes the first frame 201 of the first casing 200, via a screw 41 that serves as a fastening member. The left pillar 212a is a pillar of the first frame 201 on the front side, and the left pillar 212b is a pillar of the first frame 201 on the back side.

The second plate portion 43 is formed integrally with the first plate portion 42. In a state where the second plate portion 43 is not fastened by the fastening portion 52, the relative position of the second plate portion 43 is adjustable with respect to the second casing 300 in the X direction. Specifically, as illustrated in FIGS. 12 and 13, the second plate portion 43 that constitutes one first connecting member 40 on the front side is disposed so as to cover a portion of a right pillar 312a of the second frame 301 that constitutes the second casing 300, and the second plate portion 43 that constitutes the other first connecting member 40 on the back side is disposed so as to cover a portion of a right pillar 312b of the second frame 301 that constitutes the second casing 300. The right pillar 312a is a pillar of the second frame 301 on the front side, and the right pillar 312b is a pillar of the second frame 301 on the back side. The second plate portion 43 on the front side is disposed so as to cover a portion of the front surface of the right pillar 312a on the front side, and the second plate portion 43 on the back side is disposed so as to cover a portion of the back surface of the right pillar 312b on the back side.

For example, the first plate portion 42 and the second plate portion 43 are a one-body plate-like member made of a material such as metal. The first connecting member 40 of the present embodiment is formed by bending the second plate portion 43 at substantially right angles with respect to the first plate portion 42. The second connecting member 50 is positioned with respect to the second casing 300. In addition, in a state where the second connecting member 50 is not fastened to the first connecting member 40, the relative position of the second connecting member 50 relative to the second plate portion 43 is adjustable in the X direction.

The second connecting member 50 has the shaft 50c, and the second connecting member 50 and the shaft 50c are joined and integrated with each other. On the other hand, the second plate portion 43 of the first connecting member 40 has a long hole 40c formed in the second plate portion 43 and elongated in the X direction. In addition, the right pillar 312a of the second frame 301 has a positioning hole Ha formed in the right pillar 312a, and the right pillar 312b of the second frame 301 has a positioning hole Hb formed in the right pillar 312b. The shaft 50c of one second connecting member 50 on the front side is inserted into the positioning hole Ha through the long hole 40c of the second plate portion 43 on the front side, and the shaft 50c of the other second connecting member 50 on the back side is inserted into the positioning hole Hb through the long hole 40c of the second plate portion 43 on the back side. In this manner, the second connecting member 50 is positioned with respect to the second frame 301 in the X direction and the Z direction. Although the shaft 50c passes through the long hole 40c of the second plate portion 43, the position of the second connecting member 50 relative to the second plate portion 43 in the X direction is adjustable because the long hole 40c is elongated in the X direction. That is, the shaft 50c of one second connecting member 50 is inserted into the positioning hole Ha through the long hole 40c of one second plate portion 43, and the shaft 50c of the other second connecting member 50 is inserted into the positioning hole Hb through the long hole 40c of the other second plate portion 43, so that the second casing 300 is positioned with respect to the first casing 200 in the Z direction. In this state, however, the second casing 300 can be moved relative to the first casing 200 in the X direction.

In addition, the second connecting member 50 has a long hole 50b formed in the second connecting member 50 and elongated in the X direction, and the second plate portion 43 has a boss portion 40b formed in the second plate portion 43 so as to be able to fit in the long hole 50b. Thus, when the second connecting member 50 is positioned to the second frame 301 via the second plate portion 43 as described above, the boss portion 40b is inserted into the long hole 50b. The direction in which the shaft 50c can move along the long hole 40c formed in the second plate portion 43 is equal to the direction in which the boss portion 40b can move along the long hole 50b. Thus, the first connecting member 40 and the second connecting member 50 can move relative to each other in the X direction without rotating relative to each other. That is, as described below, when the distance between the second casing 300 and the first casing 200 is adjusted, the second connecting member 50 positioned to the second casing 300 can be moved, in the X direction, with respect to the second plate portion 43 of the first connecting member 40 fixed to the first casing 200.

Any one of the first connecting member 40 and the second connecting member 50 includes a first indicating portion 50a that serves as an indicating portion that indicates the position of the one with respect to the other in the X direction. In the present embodiment, the first indicating portion 50a is formed in the second connecting member 50, and a scale 40a is formed in the first connecting member 40. The first indicating portion 50a is a substantially triangular projection portion formed integrally with the second connecting member 50. On the other hand, the scale 40a is a plurality of grooves or engraved marks formed in a portion of the second plate portion 43 of the first connecting member 40 in the vicinity of the first indicating portion 50a, at constant intervals in the X direction. The triangular apex of the first indicating portion 50a indicates one of the plurality of grooves or engraved marks of the scale 40a, or a space between two of the plurality of grooves or engraved marks, so that the position of the second connecting member 50 relative to the first connecting member 40 in the X direction can be checked. Note that the first indicating portion 50a may be formed in the first connecting member 40, and the scale 40a may be formed in the second connecting member 50.

In addition, the first connecting member 40 includes a second indicating portion 40d that indicates the position of the first connecting member 40 with respect to the second casing 300 in the Z direction (i.e., the vertical direction). On the other hand, each of the right pillars 312a and 312b of the second frame 301 that constitutes the second casing 300 has a scale 30d formed in the right pillar. The second indicating portion 40d is a substantially triangular projection portion formed integrally with the second plate portion 43 of the first connecting member 40. On the other hand, the scale 30d is a plurality of grooves or engraved marks formed in a portion of each of the right pillars 312a and 312b in the vicinity of the second indicating portion 40d, at constant intervals in the Z direction. The triangular apex of the second indicating portion 40d indicates one of the plurality of grooves or engraved marks of the scale 30d, or a space between two of the plurality of grooves or engraved marks, so that the position of the first connecting member 40 relative to the second frame 301 in the Z direction can be checked.

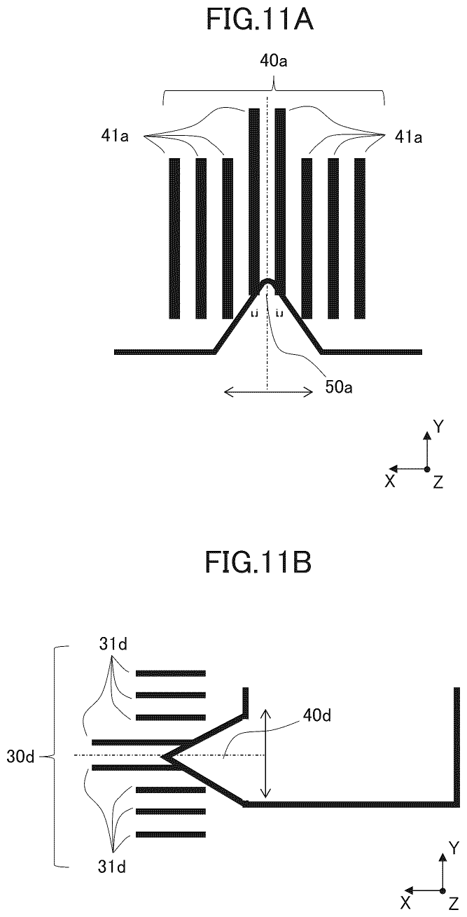

FIG. 11A illustrates a relationship between the first indicating portion 50a and the scale 40a, which are described above. FIG. 11B illustrates a relationship between the second indicating portion 40d and the scale 30d. In the present embodiment, the scale 40a is formed as engraved marks that are lines 41a formed at intervals of 1 mm, and the scale 30d is formed as engraved marks that are lines 31d formed at intervals of 1 mm.

As described above, the first connecting member 40 and the second connecting member 50 can move relative to each other in the X direction while the boss portion 40b is retained by the long hole 50b and the shaft 50c is retained by the long hole 40c. The amount of the movement can be adjusted in steps of 1 mm by positioning the first indicating portion 50a at a line 41a of the scale 40a, or at a space between adjacent lines 41a of the scale 40a. In addition, the first connecting member 40 and the right pillars 312a and 312b of the second casing 300 can move relative to each other in the Z direction by adjusting the height by using the caster 21. The amount of the movement can be adjusted in steps of 1 mm by positioning the second indicating portion 40d at a line 31d of the scale 30d, or at a space between adjacent lines 31d of the scale 30d. Note that a space between the central two long lines 41a of the plurality of lines 41a, illustrated in FIG. 11A, and a space between the central two long lines 31d of the plurality of lines 31d, illustrated in FIG. 11B, represent an initial position in which the first casing 200 and the second casing 300 are connected to each other.

As described above, the adjusting member 20 that fixes the first casing 200 and the second casing 300 has a configuration that can adjust the distance between the first casing 200 and the second casing 300 in the X direction (i.e., the first direction). The adjusting member 20 includes the first connecting member 40 fixed to the first casing 200, and the second connecting member 50 positioned with respect to the second casing 300 in the Z direction and the X direction. In a state where the first connecting member 40 and the second connecting member 50 are not fastened to each other via the screw 51, the first connecting member 40 and the second connecting member 50 can move relative to each other in the X direction. That is, the distance between the first casing 200 and the second casing 300 in the X direction (i.e., the first direction) can be adjusted.

Hereinafter, a specific configuration that allows the first connecting member 40 and the second connecting member 50 to move relative to each other in the X direction will be described. For example, the long hole 40c, into which the shaft 50c is inserted, has an opening whose size is larger than the size of the shaft 50c in the X direction, and the long hole 50b, into which the boss portion 40b is inserted, has an opening whose size is larger than the size of the boss portion 40b in the X direction. In addition, a screw hole into which the screw 51 is inserted has an opening whose size is larger than the size of the screw 51 in the X direction. This is also one of configurations that allow the above-described relative movement. In modifications of the adjusting member 20, only one of the above-described configurations may be used, or another configuration may be used instead of the above-described configurations. That is, the distance between the first casing 200 and the second casing 300 in the X direction can be adjusted in a configuration in which any value can be selected from among a plurality of candidate values, or from a predetermined numerical range for the distance between the first casing 200 and the second casing 300 in the X direction.

Next, a method of adjusting the distance between the first casing 200 and the second casing 300 by using the adjusting member 20 of the present embodiment, and a method of fixing the first casing 200 and the second casing 300 by using the adjusting member 20 will be described with reference to FIGS. 12 and 13. FIG. 12 is a diagram illustrating a process in which the first frame 201 and the second frame 301 are connected to each other by using one adjusting member 20 on the front-surface side (the front side) of the first casing 200 and the second casing 300. Similarly, FIG. 13 is a diagram illustrating a process in which the first frame 201 and the second frame 301 are connected to each other by using the other adjusting member 20 on the back-surface side (the back side) of the first casing 200 and the second casing 300.

As described above, one first connecting member 40 on the front side is fixed to the left pillar 212a of the first frame 201 via the screw 41 (see FIG. 10C), and the other first connecting member 40 on the back side is fixed to the left pillar 212b of the first frame 201 via the screw 41 (see FIG. 10C). On the other hand, one second connecting member 50 on the front side is positioned with respect to the second frame 301 in the X direction by inserting the shaft 50c, formed integrally with the second connecting member 50, into the positioning hole Ha formed in the right pillar 312a of the second frame 301, and the other second connecting member 50 on the back side is positioned with respect to the second frame 301 in the X direction by inserting the shaft 50c, formed integrally with the second connecting member 50, into the positioning hole Hb formed in the right pillar 312b of the second frame 301. After that, the distance between the first casing 200 and the second casing 300 is adjusted, and then the second connecting member 50 is fixed to the first connecting member 40 via the screw 51, as described below. With this operation, the first casing 200 and the second casing 300 are connected to each other via the adjusting member 20.

Note that, in the adjusting member 20, the first plate portion 42 is attached to the side surface of the first casing 200, and the second plate portion 43, the second connecting member 50, and the fastening screw 51 are disposed so as to project toward the second casing 300 side from the first casing 200. Each of the second plate portion 43 and the second connecting member 50 includes the indicating portion and the scale used for the adjustment. Thus, the adjustment of the distance between the first casing 200 and the second casing 300, and the positioning of the first casing 200 and the second casing 300 can be performed by using the adjusting member 20 without removing the exterior cover or the like of the first casing 200.

### Fixing Member

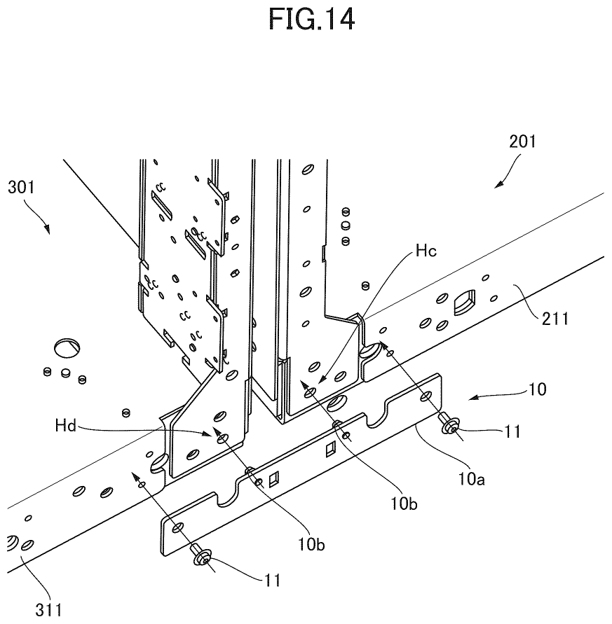

Next, the fixing member 10 will be described with reference to FIG. 14. FIG. 14 is a diagram illustrating a process in which the first frame 201 and the second frame 301 are connected to each other by using the fixing member 10 on the front-surface side (the front side) of the first casing 200 and the second casing 300. The fixing member 10 connects the first casing 200 and the second casing 300 at the first height position, positioned in the vertical direction, so that a distance (a first distance) between the first casing 200 and the second casing 300 in the first direction at the first height position is fixed. In the present embodiment, the fixing member 10 is disposed on each of both sides in the front and back direction. Thus, the fixing member 10 fixes the first casing 200 and the second casing 300 so that the distance between the first casing 200 and the second casing 300 in the X direction on the front side becomes the predetermined distance, and that the distance between the first casing 200 and the second casing 300 in the X direction on the back side becomes the predetermined distance.

In the fixing member 10, two shafts 10b are joined and integrated with a metal plate 10a. In a case where the first casing 200 and the second casing 300 are connected to each other via the fixing member 10, one of the two shafts 10b is fit in a positioning hole Hc formed in the bottom plate 211 of the first frame 201 that constitutes the first casing 200, and the other of the two shafts 10b is fit in a positioning hole Hd formed in the bottom plate 311 of the second frame 301 that constitutes the second casing 300. With this operation, the distance between the first casing 200 and the second casing 300 is fixed. Then, the metal plate 10a is fixed to the bottom plates 211 and 311 via screws 11 that serve as a fastening member, so that the first casing 200 and the second casing 300 are fixed at the first height position, by the fixing member 10.

### Fixing Positions of Fixing Member and Adjusting Member

Next, the first height position that is a fixing position of the fixing member 10, and the second height position that is a fixing position of the adjusting member 20 will be described. As described above, each of the modules that constitute the ink-jet recording apparatus 1 includes a corresponding conveyance path for conveying the recording material. Thus, the recording material is delivered from one module to another. In particular, in the present embodiment, the apparatus includes the conveyance paths 110, 101, 103, 105, and 107 which are disposed in an upper portion of the apparatus and through which the recording material is conveyed in the X direction, and the conveyance paths 108, 106, 104, 102, and 111 which are disposed below the conveyance paths 110, 101, 103, 105, and 107 and through which the sheet is conveyed, in the double-side printing, in a direction opposite to the direction in which the sheet is conveyed through the conveyance paths 110, 101, 103, 105, and 107 (FIG. 1). Thus, in a case where the upper conveyance path and the lower conveyance path are disposed so as to extend through a space between modules adjacent to each other, it is required that the clearance between the casings of the modules be constant in the vertical direction.

In the present embodiment, as described above, adjacent casings are fixed by the fixing member 10 at the first height position that is a lower portion of the casings, and the distance between the adjacent casings are adjusted by the adjusting member 20 at the second height position above the first height position and then the casings are fixed. In the present embodiment, the first height position is a position in which the bottom plate of one frame that constitutes a corresponding casing and the bottom plate of the other frame that constitutes a corresponding casing are connected to each other. In addition, the second height position is a position between the upper conveyance path and the lower conveyance path. Hereinafter, the second height position will be described, as an example, for the first casing 200 of the above-described print module 2000 and the second casing 300 of the drying module 3000.

The print module 2000 includes the upper conveyance path 101 and the lower conveyance path 102. The drying module 3000 includes the upper conveyance path 103 and the lower conveyance path 104. The conveyance path 101 is referred to as a first conveyance path, the conveyance path 103 is referred to as a second conveyance path, the conveyance path 102 is referred to as a third conveyance path, and the conveyance path 104 is referred to as a fourth conveyance path. In this case, the second height position is positioned between the first conveyance path and the third conveyance path in the vertical direction. Note that the second height position is positioned also between the second conveyance path and the fourth conveyance path in the vertical direction. Thus, the first casing 200 and the second casing 300 are connected to each other via the adjusting member 20 in the position between the upper conveyance path and the lower conveyance path. As a result, the relationship between the height of an upper conveyance path of one casing and the height of an upper conveyance path of the other casing adjacent to the one casing, and the relationship between the height of a lower conveyance path of the one casing and the height of a lower conveyance path of the other casing can be adjusted with high accuracy.

For example, in a case where the second height position, which is a connecting position of the adjusting member 20, is positioned above the upper conveyance path, the distance between the second height position and the lower conveyance path becomes too large in the vertical direction. In this case, even if the distance between the casings is adjusted at the second height position by using the adjusting member 20, it is difficult to increase the accuracy of the height of a lower conveyance path of one casing and the height of a lower conveyance path of the other casing. On the other hand, also in a case where the second height position is positioned below the lower conveyance path, it is difficult to increase the accuracy of the height of an upper conveyance path of one casing and the height of an upper conveyance path of the other casing. Note that the distance of the casings may be adjusted by adjusting members 20 in a plurality of positions in the vertical direction. However, if the number of the adjusting positions increases, the adjustment operation will be performed at each position and become troublesome.

In the present embodiment, however, since the second height position is positioned between the first conveyance path and the third conveyance path, the height adjustment of an upper conveyance path of one casing and an upper conveyance path of the other casing, and the height adjustment of a lower conveyance path of the one casing and a lower conveyance path of the other casing can be performed with high accuracy while the troublesome work can be prevented. In addition, since the first height position is positioned in the bottom plate (or the lowermost portion of the frame) that constitutes the frame of the casing, the distance between the first height position and the second height position can be made larger. In other words, the distance between the positions for fixing the casings can be made larger, and the distance between the casings can be easily made constant in the vertical direction.

### Method of Adjusting the Positions of Casings

Next, a method of adjusting the positions of adjacent casings, which is a method of adjusting the image forming apparatus of the present embodiment, will be described with reference to FIGS. 10A to 14 and FIGS. 15A to 16. In the present embodiment, in a case where the first casing 200 and the second casing 300 are connected to each other, the first casing 200 and the second casing 300 are fixed each other, at a first height position fixing process, by the fixing member 10 at the first height position positioned in the vertical direction so that the distance between the first casing 200 and the second casing 300 in the X direction becomes a predetermined distance. After the first height position fixing process, the distance between the first casing 200 and the second casing 300 in the X direction is adjusted, in a first direction adjustment process, by using the adjusting member 20 at the second height position different from the first height position in the vertical direction. Furthermore, after the first direction adjustment process, the first casing 200 and the second casing 300 are fixed each other, at a second height position fixing process, at the second height position positioned in the vertical direction.

In addition, in the present embodiment, the position of the second casing 300 with respect to the first casing 200 in the vertical direction is adjusted, in a vertical direction adjustment process, by adjusting the position of the second casing 300 in the vertical direction, by using the plurality of casters 21. The vertical direction adjustment process is performed before the first height position fixing process. As described above with reference to FIGS. 9A and 9B, in the first direction adjustment process, the distance between the first casing 200 and the second casing 300 in the X direction is adjusted by adjusting the position of the second casing 300 in the vertical direction, by using the plurality of casters 21. Hereinafter, the detailed description will be made.

As described above, in the front and back direction (i.e., the Y direction) of the first casing 200 and the second casing 300, the first casing 200 and the second casing 300 are positioned to each other, as described with reference to FIGS. 3 to 5, via the positioning shafts 202a and 202b formed in the left side-surface of the first casing 200 and the fitting holes 302a and 302b formed in the right side-surface of the second casing 300 fitting to each other. As described above, each of the fitting holes 302a and 302b is a long hole elongated along the vertical direction (i.e., the Z direction). Thus, it is necessary to additionally adjust the position of the first casing 200 and the second casing 300 in the vertical direction (i.e., the Z direction) and the right and left direction (i.e., the X direction).

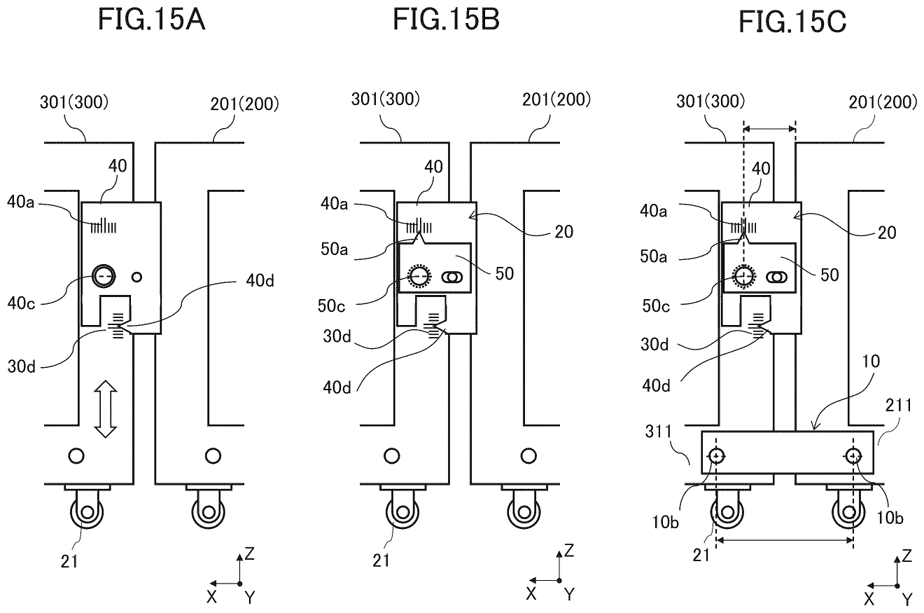

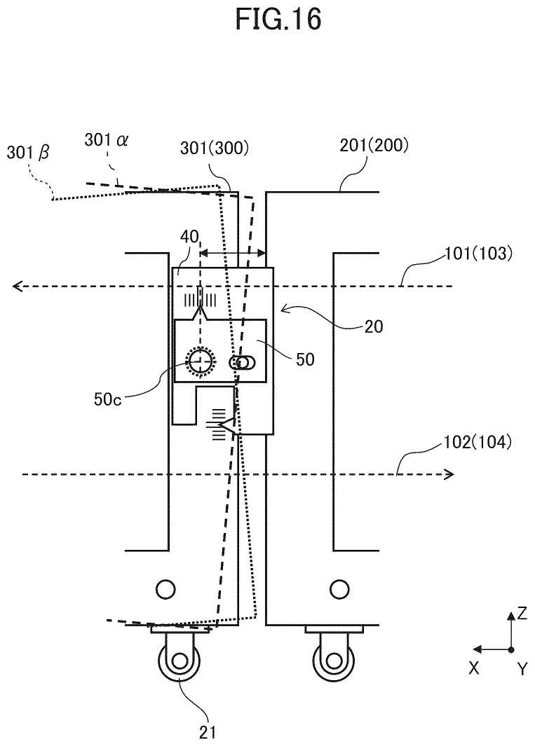

FIG. 15A is a diagram illustrating the adjustment in the Z direction, performed in the connecting operation of the first casing 200 and the second casing 300. FIG. 15B is a diagram illustrating a state where the second connecting member 50 is positioned to the second casing 300. FIG. 15C is a diagram illustrating a state where a lower portion of the first casing 200 and a lower portion of the second casing 300 are connected to each other via the fixing member 10. FIG. 16 is a diagram illustrating a state where the distance between the first casing 200 and the second casing 300 are adjusted in a state where the lower portion of the first casing 200 and the lower portion of the second casing 300 are not connected to each other via the fixing member 10.

First, the position adjustment (i.e., the height adjustment) of the first casing 200 and the second casing 300 in the vertical direction (i.e., the Z direction) will be described with reference to FIG. 15A. The first connecting member 40 of the adjusting member 20 is attached to each of two portions (formed in the front and back direction) of the left side-surface of the first frame 201, which constitutes the first casing 200. That is, the first plate portion 42 of one first connecting member 40 is fixed to the left pillar 212a, which constitutes the first frame 201, via the screw 41, and the first plate portion 42 of the other first connecting member 40 is fixed to the left pillar 212b, which constitutes the first frame 201, via the screw 41. Then, the second casing 300 is made closer to the first casing 200 by moving the second casing 300 in the X direction. As a result, a state illustrated in FIG. 15A is obtained.

Then, by using the second indicating portion 40d included in the first connecting member 40 and the scale 30d formed in each of the right pillars 312a and 312b of the second frame 301, the relative position between the first casing 200 and the second casing 300 in the Z direction is checked. Then, the height of the second casing 300 with respect to the first casing 200 is adjusted by using the caster 21 so that the second indicating portion 40d indicates a space between the central two long lines 31d (FIG. 11B) of the scale 30d (the vertical direction adjustment process).

The height adjustment of the second casing 300 with respect to the first casing 200 is performed in this manner on each of the front side and the back side. In a state where the height adjustment is completed on both of the front side and the back side, the second connecting member 50 is assembled to the first connecting member 40. That is, the shaft 50c of one second connecting member 50 is inserted into the positioning hole Ha formed in the right pillar 312a of the second frame 301, via the long hole 40c of one second plate portion 43 that constitutes one first connecting member 40, and the shaft 50c of the other second connecting member 50 is inserted into the positioning hole Hb formed in the right pillar 312b of the second frame 301, via the long hole 40c of the other second plate portion 43 that constitutes the other first connecting member 40. With this operation, as illustrated in FIG. 15B, the second casing 300 is positioned with respect to the first casing 200 in the Z direction. Note that in this state, the second casing 300 is not yet positioned in the X direction.

Then, one of the two shafts 10b of the fixing member 10 is fit in the positioning hole Hc formed in the bottom plate 211 of the first casing 200, and the other of the two shafts 10b of the fixing member 10 is fit in the positioning hole Hd formed in the bottom plate 311 of the second casing 300. Then, the fixing member 10 is fixed to the bottom plates 211 and 311 via screws 11 (the first height position fixing process). With this operation, the bottom plate 211 of the first casing 200 and the bottom plate 311 of the second casing 300 are fixed by the fixing member 10, so that a state illustrated in FIG. 15C is obtained.

Then, by using the scale 40a formed in the first connecting member 40 and the first indicating portion 50a formed in the second connecting member 50, the relative position between the first casing 200 and the second casing 300 in the X direction, obtained at the second height position, is checked. Then, as described with reference to FIGS. 9A and 9B, the distance between the second casing 300 and the first casing 200 at the second height position is adjusted by using the casters 21A to 21D so that the first indicating portion 50a indicates a space between the central two long lines 41a (FIG. 11A) of the scale 40a (the first direction adjustment process). For example, in a case where the distance between the first casing 200 and the second casing 300 in the X direction is larger in an upper portion than in a lower portion in the vertical direction, the front caster 21C and the back caster 21D on the first casing 200 side are lowered by the same amount. With this operation, the distance in the upper portion is made smaller, so that the distance between the casings is made proper in the vertical direction.

After the distance at the second height position is adjusted in the X direction, the second connecting member 50 is fastened to the first connecting member 40 via the screw 51. With this operation, the relative position between the first casing 200 and the second casing 300 in the X direction, obtained at the second height position, is fixed (the second height position fixing process). That is, since the first connecting member 40 is fixed to the first casing 200 via the screw 41, and the second connecting member 50 is positioned with respect to the first casing 200 in the Z direction by the shaft 50c, the second casing 300 is positioned with respect to the first casing 200 in the X direction by fastening the first connecting member 40 and the second connecting member 50 by using the screw 51.

By the way, as illustrated in FIG. 16, in a case where the fixing member 10 that fixes the bottom plate of the first casing 200 and the bottom plate of the second casing 300 to each other is not used, and the position adjustment is performed in the X direction by using the adjusting member 20 alone, the adjustment operation will take time. That is, if the shaft 50c of one second connecting member 50 is inserted into the positioning hole Ha formed in the right pillar 312a of the second casing 300, and the shaft 50c of the other second connecting member 50 is inserted into the positioning hole Hb formed in the right pillar 312b of the second casing 300 in a state where the first connecting member 40 of the adjusting member 20 is fixed to the first casing 200, the distance between the left side-surface of the first connecting member 40 and the positioning holes Ha and Hb of the second casing 300 is determined. However, in a case where the fixing member 10 is not used, as illustrated in FIG. 16, the second frame 301 of the second casing 300 may pivot on the shaft 50c, and the state of the second frame 301 may become a state indicated by a broken line 301α in FIG. 16 or a state indicated by a dotted line 301β in FIG. 16. In this state, the clearance between the first casing 200 and the second casing 300 is not constant in the vertical direction. Thus, since it is necessary to perform further adjustment while checking the clearance in the vertical direction, the adjustment operation will take time.

In contrast, in the present embodiment, since the fixing member 10 is used, the distance between the positioning hole Hc formed in the bottom plate 211 of the first casing 200 and the positioning hole Hd formed in the bottom plate 311 of the second casing 300 is fixed. Thus, in the present embodiment, in a state where the distance between casings to be connected to each other in the X direction is fixed at the first height position (or in a lower portion), the distance at the second height position (or an upper portion) is adjusted by using the adjusting member 20. Thus, it is prevented that the second casing 300 slants as illustrated in FIG. 16, and the position of the second casing 300 can be determined uniquely by the adjusting member 20. As a result, the distance between two casings can be easily adjusted in the vertical direction, and the time for adjusting the distance can be reduced. In particular, in a case where an apparatus, such as the ink-jet recording apparatus 1 of the present embodiment, has a larger number of casings to be connected to each other, the adjustment operation is required for each pair of adjacent casings. In this case, by performing the adjustment method of the present embodiment, the time for the adjustment operation for each pair of adjacent casings can be shortened, so that the time for installing the ink-jet recording apparatus 1 can be reduced.

In addition, the distance between casings in the X direction is required to be set with high accuracy in a case where each casing contains a conveyance path in an upper side and a conveyance path in a lower side, and where the conveyance path of one casing on the upper side is connected to the conveyance path of the other casing on the upper side and the conveyance path of the one casing on the lower side is connected to the conveyance path of the other casing on the lower side. As described above, it is preferable that the position in which the distance is adjusted by using the adjusting member 20 be set closer to the upper conveyance path and the lower conveyance path. Thus, the position is preferably set between the upper conveyance path and the lower conveyance path. In the present embodiment, the adjusting member 20 is positioned at a substantially middle point between the upper conveyance path and the lower conveyance path in the vertical direction.

### Other Embodiments

In the above-described embodiment, the fastening portion 52 includes the second connecting member 50 and the screw 51. The fastening portion 52 is included in the adjusting member 20 that fixes the first casing 200 and the second casing 300 in a state where the distance between the first casing 200 and the second casing 300 is adjusted at the second height position, and fastens the first connecting member 40 to the second casing 300. However, the adjusting member may have a configuration that includes a single connecting member, and a fastening member such as a screw. In this configuration, the single connecting member is fixed to the first casing 200 and the second casing 300 via the fastening member. For example, in a state where the connecting member is fixed to the first casing 200, the distance between the first casing 200 and the second casing 300 in the X direction may be adjusted at the second height position while an indicating portion formed in the connecting member and a scale formed in the second casing 300 are checked, and after the adjustment, the connecting member may be fixed to the second casing 300 via the screw. In this case, the fastening portion is the screw alone.

However, it is preferable that the fastening portion 52 include the second connecting member 50 and the screw 51 as in the present embodiment because the adjustment operation can be made easy. That is, in the present embodiment, the shaft 50c of one second connecting member 50 is inserted into the positioning hole Ha, and the shaft 50c of the other second connecting member 50 is inserted into the positioning hole Hb, so that the first casing 200 and the second casing 300 can be positioned in the Z direction. In this state, the distance between the first casing 200 and the second casing 300 in the X direction can be adjusted. If the adjustment of the distance between the first casing 200 and the second casing 300 in the X direction is tried in a state where the first casing 200 and the second casing 300 are not positioned in the Z direction, the relative position between the first casing 200 and the second casing 300 in the Z direction may shift, which may require the additional position adjustment in the Z direction. In contrast, in the present embodiment, since the adjustment of the distance between the first casing 200 and the second casing 300 in the X direction is performed in a state where the first casing 200 and the second casing 300 are positioned in the Z direction, the relative position between the first casing 200 and the second casing 300 in the Z direction does not shift when the distance is adjusted in the X direction, which can increase the workability.

In the above-described embodiment, the description has been made for the case where the present invention is applied to the ink-jet recording apparatus. However, the present disclosure is not limited to this. For example, the present invention can also be applied to an electrophotographic image forming apparatus that uses toner.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-077476, filed May 10, 2024, which is hereby incorporated by reference herein in its entirety.

What is claimed is:

1. An image forming apparatus configured to form an image on a recording material, the image forming apparatus comprising:
a first casing including a first conveyance path through which a recording material is conveyed;
a second casing connected to the first casing such that the first casing and the second casing are arranged along a first direction orthogonal to a vertical direction, and including a second conveyance path which is connected to the first conveyance path, and through which the recording material from the first conveyance path is conveyed;
a fixing member configured to connect the first casing and the second casing at a first height position in the vertical direction such that a first distance between the first casing and the second casing in the first direction at the first height position is fixed; and
an adjusting member configured to connect the first casing and the second casing at a second height position in the vertical direction different from the first height position such that a second distance between the first casing and the second casing in the first direction at the second height position is adjustable,
wherein, by at least the fixing member and the adjusting member, the first casing and the second casing are fixed to each other with the second distance adjusted to a predetermined distance.

2. The image forming apparatus according to claim 1, wherein the second height position is positioned above the first height position in the vertical direction.

3. The image forming apparatus according to claim 1, wherein the first casing includes a third conveyance path which is disposed below the first conveyance path in the vertical direction,
wherein the second casing includes a fourth conveyance path which is disposed below the second conveyance path in the vertical direction and is connected to the third conveyance path, and
wherein a recording material is conveyed through the third conveyance path and the fourth conveyance path.

4. The image forming apparatus according to claim 3, wherein the second height position is positioned between the first conveyance path and the third conveyance path in the vertical direction.

5. The image forming apparatus according to claim 1, wherein the adjusting member includes
a connecting member configured to connect the first casing and the second casing, and
a fastening portion configured to fasten the connecting member to the second casing, and
wherein the connecting member includes
a fixing portion configured to be fixed to the first casing, and
a changing portion that is formed integrally with the fixing portion and whose relative position with respect to the second casing in the first direction is adjustable in a state where the changing portion is not fastened by the fastening portion.

6. The image forming apparatus according to claim 5, wherein the connecting member is a first connecting member,
wherein the fastening portion includes a second connecting member configured to be positioned with respect to the second casing in the vertical direction and the first direction, and configured to be fastened to the first connecting member, and
wherein the second connecting member is configured to be positioned with respect to the second casing, and a relative position of the second connecting member relative to the changing portion in the first direction is adjustable in a state where the second connecting member is not fastened to the first connecting member.

7. The image forming apparatus according to claim 6, wherein any one member of the first connecting member and the second connecting member includes an indicating portion configured to indicate a position of the one member with respect to another member of the first connecting member and the second connecting member in the first direction.

8. The image forming apparatus according to claim 7, wherein the indicating portion is a first indicating portion, and
wherein the first connecting member includes a second indicating portion configured to indicate a position of the first connecting member with respect to the second casing in the vertical direction.

9. The image forming apparatus according to claim 1, wherein the second casing includes a plurality of vertical direction adjustment portions configured to adjust a position of the second casing with respect to an installation surface in the vertical direction, the installation surface being a surface on which the second casing is installed.

10. The image forming apparatus according to claim 9, wherein each of the plurality of vertical direction adjustment portions includes
a wheel configured to contact the installation surface, and
a vertical position changing portion that is fixed to the second casing and whose position with respect to the wheel in the vertical direction is able to be changed.

11. The image forming apparatus according to claim 1, wherein the first casing includes a first fitting portion,
wherein the second casing includes a second fitting portion configured to fit to the first fitting portion, and
wherein a relative position of the second casing with respect to the first casing in a second direction orthogonal to the vertical direction and the first direction is fixed by the first fitting portion and the second fitting portion fitting to each other.

12. An adjustment method for an image forming apparatus,
wherein the image forming apparatus is configured to form an image on a recording material and includes
a first casing including a first conveyance path through which a recording material is conveyed, and
a second casing connected to the first casing such that the first casing and the second casing are arranged along a first direction orthogonal to a vertical direction, and including a second conveyance path which is connected to the first conveyance path, and through which the recording material from the first conveyance path is conveyed,
the adjustment method comprising:
fixing a first distance between the first casing and the second casing in the first direction at a first height position in a vertical direction;
adjusting a second distance between the first casing and the second casing in the first direction at a second height position in the vertical direction different from the first height position after the first distance is fixed at the first height position; and
fixing the first casing and the second casing each other at the second height position after the second distance is adjusted.

13. The adjustment method for the image forming apparatus according to claim 12, wherein the second height position is positioned above the first height position in the vertical direction.

14. The adjustment method for the image forming apparatus according to claim 12, wherein the second casing includes a plurality of vertical direction adjustment portions that adjusts a position of the second casing with respect to an installation surface in the vertical direction, the installation surface being a surface on which the second casing is installed, and
wherein the distance between the first casing and the second casing in the first direction at the second height position is adjusted by adjusting a position of the second casing in the vertical direction by using the plurality of vertical direction adjustment portions in a state where the distance between the first casing and the second casing in the first direction at the first height position is fixed.

15. The adjustment method for the image forming apparatus according to claim 14, further comprising:
adjusting a position of the second casing with respect to the first casing in the vertical direction by adjusting the position of the second casing in the vertical direction by using the plurality of vertical direction adjustment portions.

16. The adjustment method for the image forming apparatus according to claim 15, wherein the position of the second casing with respect to the first casing in the vertical direction is adjusted before fixing the first casing and the second casing each other at the first height position.
